(19) United States
(12) Patent Application Publication
(10) Pub. No.: US 2023/0199968 A1
(43) Pub. Date: Jun. 22, 2023

(54) METHOD FOR FORMING PATTERN ON SUBSTRATE STRUCTURE WITHOUT USING MASK LAYER AND SUBSTRATE STRUCTURE

(71) Applicant: AMULAIRE THERMAL TECHNOLOGY, INC., New Taipei City (TW)

(72) Inventors: SHIH-HSI TAI, New Taipei City (TW); TUNG-HO TAO, New Taipei City (TW); TZE-YANG YEH, New Taipei City (TW)

(21) Appl. No.: 17/552,982

(22) Filed: Dec. 16, 2021

(51) Int. Cl. H05K 3/06; H05K 1/02; H05K 3/00

(52) U.S. Cl. CPC H05K 3/06; H05K 1/0201; H05K 3/0017; H05K 2201/09036; H05K 2203/0502

(57) ABSTRACT

A method for forming a pattern on a substrate structure without using a mask layer and a substrate structure are provided. The method includes providing an electrically insulating substrate structure including a thermally conductive and electrically insulating layer, forming at least one electrically conductive recess by removing one part of the electrically conductive layer by a machining process so as to form a predetermined thickness ratio between a thickness of the electrically conductive recess and a thickness of the electrically conductive layer, and removing another part of the electrically conductive layer that is reserved below the electrically conductive recess so that the electrically conductive recess forms an electrically conductive groove.

### FIELD OF THE DISCLOSURE

The present disclosure relates to a substrate structure, and more particularly to a method for forming a pattern on a substrate structure without using a mask layer and a substrate structure.

### BACKGROUND OF THE DISCLOSURE

A circuit pattern is usually formed by a metal etching process. However, when forming the circuit pattern, a large amount of chemical solution is required for an etching process of a thick metal layer, and a machining process of the thick metal layer can easily damage the substrate.

### SUMMARY OF THE DISCLOSURE

In response to the above-referenced technical inadequacies, the present disclosure provides a method for forming a pattern on a substrate structure without using a mask layer and a substrate structure.

In one aspect, the present disclosure provides a method for forming a pattern on a substrate structure without using a mask layer, which includes (a) providing an electrically insulating substrate structure including a thermally conductive and electrically insulating layer and an electrically conductive layer; the electrically conductive layer is arranged above the thermally conductive and electrically insulating layer, (b) forming at least one electrically conductive recess by removing one part of the electrically conductive layer by a machining process, so as to form a predetermined thickness ratio between a thickness of the electrically conductive recess and a thickness of the electrically conductive layer, and allowing an opening and a bottom wall of the at least one electrically conductive recess to respectively have a first reserved width and a second reserved width, so that the electrically insulating substrate structure is made into a preprocessed substrate structure, and (c) removing another part of the electrically conductive layer that is reserved between the bottom wall of the electrically conductive recess and a bottom surface of the electrically conductive layer by etching, so that the electrically conductive recess forms an electrically conductive groove, and forming an angle between one of two side walls of the electrically conductive groove and a top surface of the electrically conductive layer, so as to obtain a substrate structure having a thick electrically conductive layer that is patterned.

In certain embodiments, the thermally conductive and electrically insulating layer is made of a composite material including a polymer material and a thermally conductive powder.

In certain embodiments, when the thickness of the electrically conductive layer is from 0.5 mm to 6 mm, the predetermined thickness ratio between the thickness of the electrically conductive recess and the thickness of the electrically conductive layer is from 0.8: 1 to 1:1.

In certain embodiments, a predetermined width ratio is formed between the second reserved width and the first reserved width, and the predetermined width ratio is from 0.8: 1 to 1:1.

In certain embodiments, an opening of the electrically conductive groove has a first width, the two side walls of the electrically conductive groove have a second width therebetween, and a difference between the first width and the first reserved width plus a difference between the second width and the second reserved width is 0.5 to 2.5 times a thickness of the another part of the electrically conductive layer that is reserved between the bottom wall of the electrically conductive recess and the bottom surface of the electrically conductive layer.

In certain embodiments, the angle is greater than or equal to 90 degrees.

In another aspect, the present disclosure provides a substrate structure, which includes a thermally conductive and electrically insulating layer and an electrically conductive layer. The electrically conductive layer is arranged above the thermally conductive and electrically insulating layer. At least one electrically conductive recess is arranged in the electrically conductive layer, and the at least one electrically conductive recess is formed by removing one part of the electrically conductive layer by a machining process. A predetermined thickness ratio is formed between a thickness of the electrically conductive recess and a thickness of the electrically conductive layer. An opening of the electrically conductive recess and a bottom wall of the electrically conductive recess respectively have a first reserved width and a second reserved width, and a predetermined width ratio is formed between the second reserved width and the first reserved width.

In certain embodiments, the thickness of the electrically conductive layer is from 0.5 mm to 6 mm, and the predetermined thickness ratio between the thickness of the electrically conductive recess and the thickness of the electrically conductive layer is from 0.8: 1 to 1:1.

In certain embodiments, the electrically conductive recess is a metal electrically conductive recess formed by removing the one part of the electrically conductive layer by the machining process of milling.

In certain embodiments, the electrically conductive recess is a metal electrically conductive recess formed by removing the one part of the electrically conductive layer by the machining process of turning.

In certain embodiments, the electrically conductive recess is a metal electrically conductive recess formed by removing the one part of the electrically conductive layer by the machining process of electrical discharge machining.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a substrate structure according to one embodiment of the present disclosure;

FIG. 2 is a schematic side view of the substrate structure according to another embodiment of the present disclosure; and

FIG. 3 is a schematic side view of the substrate structure according to yet another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### Embodiments

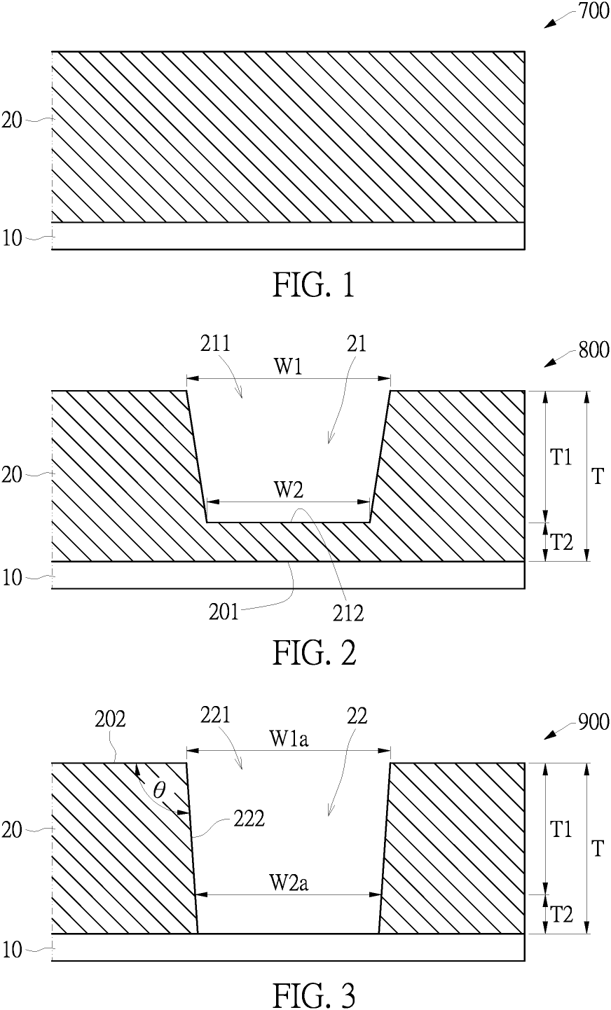

Referring to FIG. 1 to FIG. 3, one particular embodiment of the present disclosure provides a method for forming a pattern on a substrate structure without using a mask layer, which includes the following steps.

In step (a), an electrically insulating substrate structure 700 is provided as shown in FIG. 1. The electrically insulating substrate structure 700 includes a thermally conductive and electrically insulating layer 10 and an electrically conductive layer 20 that is arranged above the thermally conductive and electrically insulating layer 10.

More specifically, the thermally conductive and electrically insulating layer 10 is made of a composite material including a polymer material and a thermally conductive powder (e.g., a ceramic powder) so as to achieve a thermally conductive and electrically insulating effect. The electrically conductive layer 20 is a thick electrically conductive layer having a predetermined thickness that is made of metal. In one exemplary embodiment, a thickness T of the electrically conductive layer 20 is from 0.5 mm to 6 mm.

In step (b), as shown in FIG. 2, one part of the electrically conductive layer 20 is removed by a machining process so as to form at least one electrically conductive recess 21, a predetermined thickness ratio is allowed to be formed between a thickness T1 of the electrically conductive recess 21 and the thickness T of the electrically conductive layer 20; that is, a thickness of the metal layer (i.e., a depth of the metal layer) removed by the machining process is related to the thickness T of the electrically conductive layer 20, and an opening 211 and a bottom wall 212 of the electrically conductive recess 21 respectively are allowed to have a first reserved width W1 and a second reserved width W2 to form a predecessor of the pattern, so that the electrically insulating substrate structure 700 as shown in FIG. 1 is made into a preprocessed substrate structure 800, i.e., a semi-finished product, as shown in FIG. 2.

In one exemplary embodiment, the one part of the electrically conductive layer 20 is removed by milling, so as to form the at least one electrically conductive recess 21.

In one exemplary embodiment, the one part of the electrically conductive layer 20 is removed by a turning process, so as to form the at least one electrically conductive recess 21.

In one exemplary embodiment, the one part of the electrically conductive layer 20 is removed by electrical discharge machining, so as to form the at least one electrically conductive recess 21.

Furthermore, a predetermined width ratio is formed between the width W2 of the bottom wall 212 of the electrically conductive recess 21 and the width W1 of the opening 211 of the electrically conductive recess 21, and the predetermined width ratio is from 0.8: 1 to 1:1.

In step (c), as shown in FIG. 3, another part of the electrically conductive layer that is reserved between the bottom wall 212 of the electrically conductive recess 21 and a bottom surface 201 of the electrically conductive layer 20 as shown in FIG. 2, that is, a remaining part of the electrically conductive layer that is directly below the bottom wall 212 of the electrically conductive recess 21, is removed by etching (e.g., anisotropic etching), so that the electrically conductive recess 21 is made into an electrically conductive groove 22, and an angle θ is formed between one of two side walls 222 of the electrically conductive groove 22 and a top surface 202 of the electrically conductive layer 20, so as to obtain a substrate structure having the thick electrically conductive layer that is patterned 900.

Further, in order to allow an opening 221 of the electrically conductive groove 22 to have a first predetermined width W1a and the two side walls 222 of the electrically conductive groove 22 (i.e., two parts of the two side walls 222 being within a range defined by a thickness T2 of the another part of the electrically conductive layer that is reserved between the bottom wall 212 of the electrically conductive recess 21 and the bottom surface 201 of the electrically conductive layer 20) to have a second predetermined width W2a therebetween, a difference between the first predetermined width W1a after etching and the first reserved width W1 before etching, plus a difference between the second predetermined width W2a after etching and the second reserved width W2 before etching, is 0.5 to 2.5 times the thickness T2 of the another part of the electrically conductive layer that is reserved between the bottom wall 212 of the electrically conductive recess 21 and the bottom surface 201 of the electrically conductive layer 20. Moreover, the angle θ, which is formed after etching, between the side wall 222 of the electrically conductive groove 22 and the top surface 202 of the electrically conductive layer 20 is greater than or equal to 90 degrees.

In addition, when the thickness T of the electrically conductive layer 20 is from 0.5 mm to 6 mm, the predetermined thickness ratio between the thickness T1 of the electrically conductive recess 21 and the thickness T of the electrically conductive layer 20 is from 0.8: 1 to 1:1.

Furthermore, according to the above, another particular embodiment of the present disclosure provides a substrate structure, such as the preprocessed substrate structure 800 as shown in FIG. 2, which includes a thermally conductive and electrically insulating layer 10 and an electrically conductive layer 20 arranged on the thermally conductive and electrically conductive layer 10. At least one electrically conductive recess 21 is arranged in the electrically conductive layer 20. The at least one electrically conductive recess 21 is formed by removing one part of the electrically conductive layer 20 by a machining process, and a predetermined thickness ratio is formed between a thickness T1 of the electrically conductive recess 21 and a thickness T of the electrically conductive layer 20. An opening 211 of the electrically conductive recess 21 and a bottom wall 212 of the electrically conductive recess 21 respectively have a first reserved width W1 and a second reserved width W2, and a predetermined width ratio is formed between the second reserved width W2 and the first reserved width W1.

In one exemplary embodiment, the electrically conductive recess 21 is a metal electrically conductive recess formed by removing the one part of the electrically conductive layer 20 by milling.

In one exemplary embodiment, the electrically conductive recess 21 is a metal electrically conductive recess formed by removing the one part of the electrically conductive layer 20 by a turning process.

In one exemplary embodiment, the electrically conductive recess 21 is a metal electrically conductive recess formed by removing the one part of the electrically conductive layer 20 by electrical discharge machining.

In one exemplary embodiment, when the thickness T of the electrically conductive layer 20 is from 0.5 mm to 6 mm, the predetermined thickness ratio between a thickness T1 of the electrically conductive recess 21 and the thickness T of the electrically conductive layer 20 is from 0.8:1 to 1:1.

In one exemplary embodiment, the predetermined width ratio between the second reserved width W2 and the first reserved width W1 is from 0.8:1 to 1:1.

Furthermore, yet another particular embodiment of the present disclosure provides a substrate structure, such as the substrate structure having the thick electrically conductive layer that is patterned 900 as shown in FIG. 3, which includes a thermally conductive and electrically insulating layer 10 and an electrically conductive layer 20 arranged on the thermally conductive and electrically conductive layer 10. The electrically conductive layer 20 has at least one electrically conductive groove 22 arranged therein, and the at least one electrically conductive groove 22 has the thermally conductive and electrically insulating layer 10 that is exposed. Moreover, the electrically conductive groove 22 is formed by a machining process and by etching without using a mask layer. Accordingly, an angle θ of greater than or equal to 90 degrees is formed between a side wall 222 of the electrically conductive groove 22 and a top surface 202 of the electrically conductive layer 20.

### Beneficial Effects of the Embodiments

In conclusion, in the method for forming the pattern on the substrate structure without using the mask layer provided by the present disclosure, by virtue of “providing the electrically insulating substrate structure including the thermally conductive and electrically insulating layer and the electrically conductive layer that is arranged above the thermally conductive and electrically insulating layer”, “forming the at least one electrically conductive recess by removing the one part of the electrically conductive layer by the machining process, so as to form the predetermined thickness ratio between the thickness of the electrically conductive recess and the thickness of the electrically conductive layer, and allowing the opening and the bottom wall of the at least one electrically conductive recess to respectively have the first reserved width and the second reserved width, so that the electrically insulating substrate structure is made into the preprocessed substrate structure”, and “removing the another part of the electrically conductive layer that is reserved between the bottom wall of the electrically conductive recess and the bottom surface of the electrically conductive layer by etching, so that the electrically conductive recess is made into the electrically conductive groove, and forming the angle between the side wall of the electrically conductive groove and the top surface of the electrically conductive layer, so as to obtain the substrate structure having the thick electrically conductive layer that is patterned,” the electrically conductive layer having the predetermined thickness is pre-formed with the electrically conductive recess by the machining process, and the predetermined thickness ratio is formed between the thickness of the electrically conductive recess resulting from the machining process and the thickness of the electrically conductive layer, so as to facilitate subsequent etching process and reduce an amount of etching chemical solution that is used, thereby speeding up production and reducing costs associated therewith. Moreover, through preforming the electrically conductive recess, the thermally conductive and electrically insulating layer that is arranged below the electrically conductive layer can be effectively prevented from direct damage, vibration damage, or collapsing inward, which results in a significant decrease in bonding strength, insulating property, and thermal conductivity.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for forming a pattern on a substrate structure without using a mask layer, comprising:
(a) providing an electrically insulating substrate structure including a thermally conductive and electrically insulating layer and an electrically conductive layer, wherein the electrically conductive layer is arranged above the thermally conductive and electrically insulating layer;
(b) forming at least one electrically conductive recess by removing one part of the electrically conductive layer by a machining process, so as to form a predetermined thickness ratio between a thickness of the electrically conductive recess and a thickness of the electrically conductive layer, and allowing an opening and a bottom wall of the at least one electrically conductive recess to respectively have a first reserved width and a second reserved width, so that the electrically insulating substrate structure is made into a preprocessed substrate structure; and
(c) removing another part of the electrically conductive layer that is reserved between the bottom wall of the electrically conductive recess and a bottom surface of the electrically conductive layer by etching, so that the electrically conductive recess forms an electrically conductive groove, and forming an angle between one of two side walls of the electrically conductive groove and a top surface of the electrically conductive layer, so as to obtain a substrate structure having a thick electrically conductive layer that is patterned.

2. The method according to claim 1, wherein the thermally conductive and electrically insulating layer is made of a composite material including a polymer material and a thermally conductive powder.

3. The method according to claim 1, wherein, when the thickness of the electrically conductive layer is from 0.5 mm to 6 mm, the predetermined thickness ratio between the thickness of the electrically conductive recess and the thickness of the electrically conductive layer is from 0.8:1 to 1:1.

4. The method according to claim 1, wherein a predetermined width ratio is formed between the second reserved width and the first reserved width, and the predetermined width ratio is from 0.8: 1 to 1:1.

5. The method according to claim 1, wherein an opening of the electrically conductive groove has a first width, the two side walls of the electrically conductive groove have a second width therebetween, and a difference between the first width and the first reserved width plus a difference between the second width and the second reserved width is 0.5 to 2.5 times a thickness of the another part of the electrically conductive layer that is reserved between the bottom wall of the electrically conductive recess and the bottom surface of the electrically conductive layer.

6. The method according to claim 1, wherein the angle is greater than or equal to 90 degrees.

7. A substrate structure, comprising:
a thermally conductive and electrically insulating layer; and
an electrically conductive layer arranged above the thermally conductive and electrically insulating layer;
wherein at least one electrically conductive recess is arranged in the electrically conductive layer, and the at least one electrically conductive recess is formed by removing one part of the electrically conductive layer by a machining process;
wherein a predetermined thickness ratio is formed between a thickness of the electrically conductive recess and a thickness of the electrically conductive layer;
wherein an opening of the electrically conductive recess and a bottom wall of the electrically conductive recess respectively have a first reserved width and a second reserved width, and a predetermined width ratio is formed between the second reserved width and the first reserved width.

8. The substrate structure according to claim 7, wherein the thickness of the electrically conductive layer is from 0.5 mm to 6 mm, and the predetermined thickness ratio between the thickness of the electrically conductive recess and the thickness of the electrically conductive layer is from 0.8: 1 to 1:1.

9. The substrate structure according to claim 7, wherein the electrically conductive recess is a metal electrically conductive recess formed by removing the one part of the electrically conductive layer by the machining process of milling.

10. The substrate structure according to claim 7, wherein the electrically conductive recess is a metal electrically conductive recess formed by removing the one part of the electrically conductive layer by the machining process of turning.

11. The substrate structure according to claim 7, wherein the electrically conductive recess is a metal electrically conductive recess formed by removing the one part of the electrically conductive layer by the machining process of electrical discharge machining.

12. The substrate structure according to claim 7, wherein the predetermined width ratio between the second reserved width and the first reserved width is from 0.8:1 to 1:1.
